(19) United States
(12) Patent Application Publication
(10) Pub. No.: US 2026/0212062 A1
(43) Pub. Date: Jul. 23, 2026

(54) AUTOMATICALLY GENERATING ON-DEMAND WIRING ELEMENT OPTIMIZED MESHES FOR AUGMENTED REALITY (AR) DEVICES

(71) Applicant: Volvo Truck Corporation, Göteborg (SE)

(72) Inventors: Vincent Barnoux, St Genis Laval (FR); Kevin Lemee, Lyon (FR); Andreas Höglind, Torslanda (SE)

(21) Appl. No.: 19/411,480

(22) Filed: Dec. 8, 2025

(30) Foreign Application Priority Data
Jan. 23, 2025 (EP) 25153450.9

(51) Int. Cl. G06F 30/15

(52) U.S. Cl. CPC G06F 30/15

(57) ABSTRACT

Automatically generating on-demand wiring element optimized meshes for augmented reality (AR) devices is disclosed herein. In one example, a computer system comprises processing circuitry configured to obtain a structured file corresponding to a wiring element of a non-virtual device, wherein the structured file comprises wiring element metadata that comprises a first connector terminal descriptor, a second connector terminal descriptor, and a segment descriptor; the segment descriptor corresponds to a plurality of point descriptors; each point descriptor of the plurality of point descriptors comprises a location coordinate; and the structured file omits mesh geometry data for the wiring element. The processing circuitry further generates a three-dimensional (3D) mesh for the wiring element based on the structured file, receive visual imagery data of the non-virtual device, and display a rendering of the 3D mesh overlaid on the visual imagery data of the non-virtual device.

### TECHNICAL FIELD

The present application claims priority to European Patent Application No. 25153450.9, filed on Jan. 23, 2025, and entitled “AUTOMATICALLY GENERATING ON-DEMAND WIRING ELEMENT OPTIMIZED MESHES FOR AUGMENTED REALITY (AR) DEVICES,” which is incorporated herein by reference in its entirety.

### TECHNICAL FIELD

The disclosure relates generally to the use of augmented reality (AR) devices to visualize elements of non-virtual devices such as vehicles and/or industrial machines. In particular aspects, the disclosure relates to the automatic generation of on-demand optimized meshes for displaying wiring elements of non-virtual devices using AR devices.

The disclosure can be applied to heavy-duty vehicles, such as trucks, buses, and construction equipment, among other vehicle types. Although the disclosure may be described with respect to a particular vehicle, the disclosure is not restricted to any particular vehicle.

### BACKGROUND

Augmented reality (AR), as used herein, refers to computer-implemented techniques for generating a three-dimensional (3D) rendering in which computer-generated digital information or virtual objects are overlaid onto a non-virtual real-world environment. AR devices, such as smartphones, tablet devices, and specialized AR headsets or glasses (as non-limiting examples), capture visual imagery data of a non-virtual scene, identify non-virtual objects and surfaces within that non-virtual scene, and project virtual objects onto a user's field of vision. In this manner, an AR device can generate an immersive environment in which the user can view and/or interact with the virtual objects as if they existed in the non-virtual scene.

AR can be particularly useful for assisting technicians in visualizing elements of a non-virtual device (e.g., a vehicle, as a non-limiting example) for purposes of maintenance and repair. For example, a technician may need to identify and visualize a wiring element (such as a specific wire, a wire bundle, a wiring harness, and/or the like) of a vehicle. FIG. 1A illustrates an exemplary wiring harness 100 viewed in isolation (e.g., as it may appear in a manufacturer repair manual). The wiring harness 100 may be a component of a vehicle engine such as the vehicle engine 102 shown in FIG. 1B, and/or may extend throughout a vehicle chassis such as the vehicle chassis 104 of FIG. 1C. Consequently, it may be difficult for the technician to locate the wiring harness 100 when visually examining the vehicle engine 102 and/or the vehicle chassis 104. In this regard, an AR device may be used to project a virtual representation of the wiring harness 100 over visual imagery of the vehicle engine 102 and/or the vehicle chassis 104, allowing the technician to more easily identify the wiring element and visualize its location relative to other elements of the vehicle.

Using AR as described above for maintenance and repair of a wiring element may be conventionally accomplished by first identifying key points of flow of the wiring element, and generating a Computer-Aided Design (CAD) model of the wiring element through those key points of flow. The CAD model is represented by a CAD native data file that includes a detailed digital representation of the wiring element, including its geometry, dimensions, and other attributes and metadata. The CAD native data file may then be “decimated,” or simplified into a data file of smaller size and reduced complexity, and the decimated data file may be transmitted to an AR device. The AR device can use the decimated data file to visualize the wiring element by generating a 3D mesh that is overlaid on visual imagery data of the vehicle.

However, this conventional approach may suffer from shortcomings in some scenarios. In particular, the conversion of a CAD native data file into a decimated data file may seek to strike a balance among competing goals such as optimizing visual quality for user experience, minimizing polygon count to improve device performance, and minimizing file size to reduce transmission time and processing requirements. In the specific case of AR visualization of wiring elements of a vehicle, the relatively large number of polygons used to generate a CAD model of a wiring element generally results in a decimated data file that has a size too large to be easily downloaded to an AR device, and that may be difficult to optimize while retaining sufficient visual quality. Moreover, a conventional decimated data file may not allow enough flexibility to render a single wire, as the original CAD native data file may have been generated at a wire bundle level.

### SUMMARY

Exemplary aspects disclosed herein include automatically generating on-demand wiring element optimized meshes for augmented reality (AR) devices. In an exemplary aspect, a computer system provides processing circuitry (e.g., as part of an AR device) that is configured to obtain a structured file corresponding to a wiring element of a non-virtual device (such as a vehicle, as a non-limiting example). The structured file comprises wiring element metadata that comprises a first connector terminal descriptor, a second connector terminal descriptor, and a segment descriptor that corresponds to a segment of the wiring element. Additionally, the segment descriptor corresponds to a plurality of point descriptors that each comprises a location coordinate. The structured file otherwise omits mesh geometry data for the wiring element.

The processing circuitry then generates a three-dimensional (3D) mesh for the wiring element based on the structured file. The processing circuitry subsequently receives visual imagery data of the non-virtual device, and displays a rendering of the 3D mesh overlaid on the visual imagery data of the non-virtual device. In this manner, the examples disclosed herein may provide faster downloading of visualization data, faster AR rendering, and greater visualization customization.

In some examples, the processing circuitry of the computer system (e.g., as part of a computing device that may be separate from the AR device) is configured to first obtain a Computer-Aided Design (CAD) native data file corresponding to the wiring element of the non-virtual device, and generate the structured file based on the CAD native data file. Some such examples may provide that generating the structured file is accomplished by identifying a CAD data element within the CAD native data file that corresponds to, e.g., the first connector terminal descriptor, the second connector terminal descriptor, the segment descriptor, or a point descriptor of the plurality of point descriptors of the segment descriptor. The processing circuitry then generates the wiring element metadata based on the identified CAD data element and stores the structured file.

Some examples may further provide that the processing circuitry of the computer system (e.g., the AR device) receives a first user input indicating a selection of the non-virtual device, and subsequently obtains the structured file responsive to the first user input. According to some examples, the processing circuitry may receive a second user input that indicates a selection of the wiring element, and subsequently generates the 3D mesh responsive to the second user input.

In some examples, generating the 3D mesh may be accomplished by the processing circuitry performing a series of operations. The processing circuitry may first determine a polygon count for the segment, based on a length of the segment and the location coordinates of the plurality of point descriptors of the segment descriptor. Some such examples may further provide that each point descriptor of the plurality of point descriptors further comprises one or more corresponding tangent descriptors, and determining the polygon count for the segment is further based on the one or more tangent descriptors of the plurality of point descriptors of the segment descriptor. The processing circuitry then renders the segment using the determined polygon count.

According to a first aspect of the disclosure, a computer system is provided. The computer system comprises processing circuitry that is configured to obtain a structured file corresponding to a wiring element of a non-virtual device, wherein the structured file comprises wiring element metadata that comprises a first connector terminal descriptor, a second connector terminal descriptor, and a segment descriptor corresponding to a segment of the wiring element; the segment descriptor corresponds to a plurality of point descriptors; each point descriptor of the plurality of point descriptors comprises a location coordinate; and the structured file omits mesh geometry data for the wiring element. The processing circuitry is further configured to generate a 3D mesh for the wiring element based on the structured file, receive visual imagery data of the non-virtual device, and display a rendering of the 3D mesh overlaid on the visual imagery data of the non-virtual device. A technical benefit may include faster downloading of data and faster loading of visualizations due to the omission of mesh geometry data, as well as greater visualization customization (such as, e.g., a more granular view of each individual wiring element).

Optionally in some examples, including at least one preferred example, the processing circuitry is further configured to obtain a CAD native data file corresponding to the wiring element, generate the structured file based on the CAD native data file, and store the structured file. A technical benefit may include backwards compatibility with existing CAD systems and associated native data files, and improved performance by preprocessing the CAD native data file into the structured file prior to use.

Optionally in some examples, including at least one preferred example, the processing circuitry is configured to generate the structured file based on the CAD native data file by being configured to identify a CAD data element within the CAD native data file that corresponds to one of the first connector terminal descriptor, the second connector terminal descriptor, the segment descriptor, and a point descriptor of the plurality of point descriptors of the segment descriptor. The processing circuitry is also configured to generate the wiring element metadata based on the identified CAD data element. A technical benefit may include efficient generation of the structured file by processing only CAD data elements required to generate the 3D mesh.

Optionally in some examples, including at least one preferred example, the processing circuitry is configured to generate the 3D mesh for the wiring element based on the structured file by being configured to determine a polygon count for the segment, based on a length of the segment and the location coordinates of the plurality of point descriptors of the segment descriptor, and render the segment using the determined polygon count. A technical benefit may include more efficient rendering of the segment using a custom polygon count that is determined based on the characteristics of the segment.

Optionally in some examples, including at least one preferred example, each point descriptor of the plurality of point descriptors further comprises one or more corresponding tangent descriptors, and the processing circuitry is configured to determine the polygon count for the segment further based on the one or more tangent descriptors of the plurality of point descriptors of the segment descriptor. A technical benefit may include more accurate rendering of the segment by taking into account the tangent descriptors of each point descriptor of the segment.

Optionally in some examples, including at least one preferred example, the processing circuitry is further configured to receive a first user input indicating a selection of the non-virtual device, and obtain the structured file corresponding to the wiring element of the non-virtual device responsive to the first user input. A technical benefit may include increased flexibility by enabling 3D meshes to be generated for different non-virtual devices.

Optionally in some examples, including at least one preferred example, the processing circuitry is further configured to receive a second user input indicating a selection of the wiring element, and generate the 3D mesh based on the structured file responsive to the second user input. A technical benefit may include further increased flexibility by enabling 3D meshes to be generated for different wiring elements within a given non-virtual device.

Optionally in some examples, including at least one preferred example, the wiring element comprises one of a wire, a wiring bundle, and a wiring harness. A technical benefit may include additional flexibility by enabling 3D meshes to be generated for a variety of different types of wiring elements.

Optionally in some examples, including at least one preferred example, the non-virtual device comprises a vehicle. A technical benefit may include extending the usefulness of aspects described herein to scenarios involving wiring elements of vehicles.

According to a second aspect of the disclosure, a computer-implemented method is provided. The method comprises processing circuitry of a computer system obtaining a structured file corresponding to a wiring element of a non-virtual device, wherein the structured file comprises wiring element metadata that comprises a first connector terminal descriptor, a second connector terminal descriptor, and a segment descriptor corresponding to a segment of the wiring element; the segment descriptor corresponds to a plurality of point descriptors; each point descriptor of the plurality of point descriptors comprises a location coordinate; and the structured file omits mesh geometry data for the wiring element. The method further comprises the processing circuitry generating a 3D mesh for the wiring element based on the structured file, receiving visual imagery data of the non-virtual device, and displaying a rendering of the 3D mesh overlaid on the visual imagery data of the non-virtual device. A technical benefit may include faster downloading of data, faster loading of visualizations, and greater visualization customization (such as, e.g., a more granular view of each individual wiring element).

Optionally in some examples, including at least one preferred example, the method further comprises the processing circuitry obtaining, a CAD native data file corresponding to the wiring element, generating the structured file based on the CAD native data file, and storing the structured file. A technical benefit may include backwards compatibility with existing CAD systems and associated native data files, and improved performance by preprocessing the CAD native data file into the structured file prior to use.

Optionally in some examples, including at least one preferred example, the method comprises the processing circuitry generating the structured file based on the CAD native data file by identifying a CAD data element within the CAD native data file that corresponds to one of the first connector terminal descriptor, the second connector terminal descriptor, the segment descriptor, and a point descriptor of the plurality of point descriptors of the segment descriptor, and generating the wiring element metadata based on the identified CAD data element. A technical benefit may include efficient generation of the structured file by processing only CAD data elements required to generate the 3D mesh.

Optionally in some examples, including at least one preferred example, the method comprises the processing circuitry generating the 3D mesh for the wiring element based on the structured file by determining a polygon count for the segment, based on a length of the segment and the location coordinates of the plurality of point descriptors of the segment descriptor, and rendering the segment using the determined polygon count. A technical benefit may include more efficient rendering of the segment using a custom polygon count that is determined based on the characteristics of the segment.

Optionally in some examples, including at least one preferred example, each point descriptor of the plurality of point descriptors further comprises one or more corresponding tangent descriptors, and the method comprises determining the polygon count for the segment further based on the one or more tangent descriptors of the plurality of point descriptors of the segment descriptor. A technical benefit may include more accurate rendering of the segment by taking into account the tangent descriptors of each point descriptor of the segment.

Optionally in some examples, including at least one preferred example, the method further comprises the processing circuitry receiving a first user input indicating a selection of the non-virtual device, wherein obtaining the structured file corresponding to the wiring element of the non-virtual device is responsive to the first user input. A technical benefit may include increased flexibility by enabling 3D meshes to be generated for different non-virtual devices.

Optionally in some examples, including at least one preferred example, the method further comprises the processing circuitry receiving a second user input indicating a selection of the wiring element, wherein generating the 3D mesh based on the structured file is responsive to the second user input. A technical benefit may include further increased flexibility by enabling 3D meshes to be generated for different wiring elements within a given non-virtual device.

Optionally in some examples, including at least one preferred example, the wiring element comprises one of a wire, a wiring bundle, and a wiring harness. A technical benefit may include additional flexibility by enabling 3D meshes to be generated for a variety of different types of wiring elements.

Optionally in some examples, including at least one preferred example, the non-virtual device comprises a vehicle. A technical benefit may include extending the usefulness of aspects described herein to scenarios involving wiring elements of vehicles.

Optionally in some examples, including at least one preferred example, a computer program product is provided. The computer program product comprises program code for performing, when executed by the processing circuitry, any of the aforementioned methods, and may be associated with the above-discussed technical benefits.

Optionally in some examples, including at least one preferred example, a non-transitory computer-readable storage medium is provided. The non-transitory computer-readable storage medium comprises instructions, which, when executed by the processing circuitry, cause the processing circuitry to perform any of the aforementioned methods, and may be associated with the above-discussed technical benefits.

The disclosed aspects, examples (including any preferred examples), and/or accompanying claims may be suitably combined with each other as would be apparent to anyone of ordinary skill in the art. Additional features and advantages are disclosed in the following description, claims, and drawings, and in part will be readily apparent therefrom to those skilled in the art or recognized by practicing the disclosure as described herein.

There are also disclosed herein computer systems, control units, code modules, methods, computer readable media, and computer program products associated with the above discussed technical benefits.

### BRIEF DESCRIPTION OF THE DRAWINGS

Examples are described in more detail below with reference to the appended drawings.

FIGS. 1A-1C are diagrams illustrating an exemplary wiring harness, an engine, and a truck chassis, respectively, for which the examples disclosed herein may be used to visualize for purposes of maintenance and repair according to an example;

FIG. 2 is an exemplary system diagram of a computer system including an augmented reality (AR) device configured to automatically generating on-demand wiring element optimized meshes according to an example;

FIG. 3 is a block diagram illustrating exemplary constituent elements of the Computer-Aided Design (CAD) native data file of FIG. 2 and a corresponding exemplary segment of FIG. 2 according to an example;

FIG. 4 is a block diagram illustrating exemplary constituent elements of the structured file of FIG. 2 according to an example;

FIGS. 5A-5C provide a flowchart illustrating exemplary operations for automatically generating on-demand wiring element optimized meshes according to an example;

FIG. 6 is another view of FIG. 2, according to an example;

FIG. 7 provides a flow chart illustrating exemplary operations for automatically generating on-demand wiring element optimized meshes according to an example; and

FIG. 8 is a schematic diagram of an exemplary computer system for implementing examples disclosed herein, according to an example.

### DETAILED DESCRIPTION

The detailed description set forth below provides information and examples of the disclosed technology with sufficient detail to enable those skilled in the art to practice the disclosure.

Exemplary aspects disclosed herein include automatically generating on-demand wiring element optimized meshes for augmented reality (AR) devices. In an exemplary aspect, a computer system provides processing circuitry (e.g., as part of an AR device) that is configured to obtain a structured file corresponding to a wiring element of a non-virtual device (such as a vehicle, as a non-limiting example). The structured file comprises wiring element metadata that comprises a first connector terminal descriptor, a second connector terminal descriptor, and a segment descriptor that corresponds to a segment of the wiring element. Additionally, the segment descriptor corresponds to a plurality of point descriptors that each comprises a location coordinate. The structured file otherwise omits mesh geometry data for the wiring element.

The processing circuitry then generates a three-dimensional (3D) mesh for the wiring element based on the structured file. The processing circuitry subsequently receives visual imagery data of the non-virtual device, and displays a rendering of the 3D mesh overlaid on the visual imagery data of the non-virtual device. In this manner, the examples disclosed herein provide faster downloading of visualization data, faster AR rendering, and greater visualization customization.

In some examples, the processing circuitry of the computer system (e.g., as part of a computing device that may be separate from the AR device) is configured to first obtain a Computer-Aided Design (CAD) native data file corresponding to the wiring element of the non-virtual device, and generate the structured file based on the CAD native data file. Some such examples may provide that generating the structured file is accomplished by identifying a CAD data element within the CAD native data file that corresponds to, e.g., the first connector terminal descriptor, the second connector terminal descriptor, the segment descriptor, or a point descriptor of the plurality of point descriptors of the segment descriptor. The processing circuitry then generates the wiring element metadata based on the identified CAD data element and stores the structured file.

Some examples may further provide that the processing circuitry of the computer system (e.g., the AR device) receives a first user input indicating a selection of the non-virtual device, and subsequently obtains the structured file responsive to the first user input. According to some examples, the processing circuitry may receive a second user input that indicates a selection of the wiring element, and subsequently generates the 3D mesh responsive to the second user input.

In some examples, generating the 3D mesh may be accomplished by the processing circuitry performing a series of operations. The processing circuitry may first determine a polygon count for the segment, based on a length of the segment and the location coordinates of the plurality of point descriptors of the segment descriptor. Some such examples may further provide that each point descriptor of the plurality of point descriptors further comprises one or more corresponding tangent descriptors, and determining the polygon count for the segment is further based on the one or more tangent descriptors of the plurality of point descriptors of the segment descriptor. The processing circuitry then renders the segment using the determined polygon count.

As noted above, AR may be conventionally employed to visualize elements of a non-virtual device such as a vehicle for purposes of maintenance and repair. One use case involves using AR to view a virtual representation of a wiring element (e.g., a specific wire, a wire bundle, a wiring harness, and/or the like, as non-limiting examples) overlaid over non-virtual visual imagery data of the vehicle. This can assist a technician with identifying the wiring element and visualizing its location relative to other elements of the vehicle. Conventional approaches to applying AR in this use case may employ a CAD model that indicates key points of flow of the wiring element to generate a decimated data file of smaller size and reduced complexity. The decimated data file may then be used by an AR device to generate a 3D mesh that is overlaid on visual imagery data of the vehicle.

However, this conventional approach may suffer from shortcomings in some scenarios. In particular, conventional conversion of a CAD native data file into a decimated data file may seek to strike a balance between optimizing visual quality for user experience, minimizing polygon count to improve device performance, and minimizing file size to reduce transmission time and processing requirements. In the specific case of AR visualization of wiring elements of a vehicle, the relatively large number of polygons used to generate a CAD model of a wiring element may result in a decimated data file that is too large to be easily downloaded to an AR device, and that may be difficult to optimize while retaining sufficient visual quality. Moreover, a conventional decimated data file may not allow enough flexibility to render a single wire, as the original CAD native data file may have been generated at a wire bundle level.

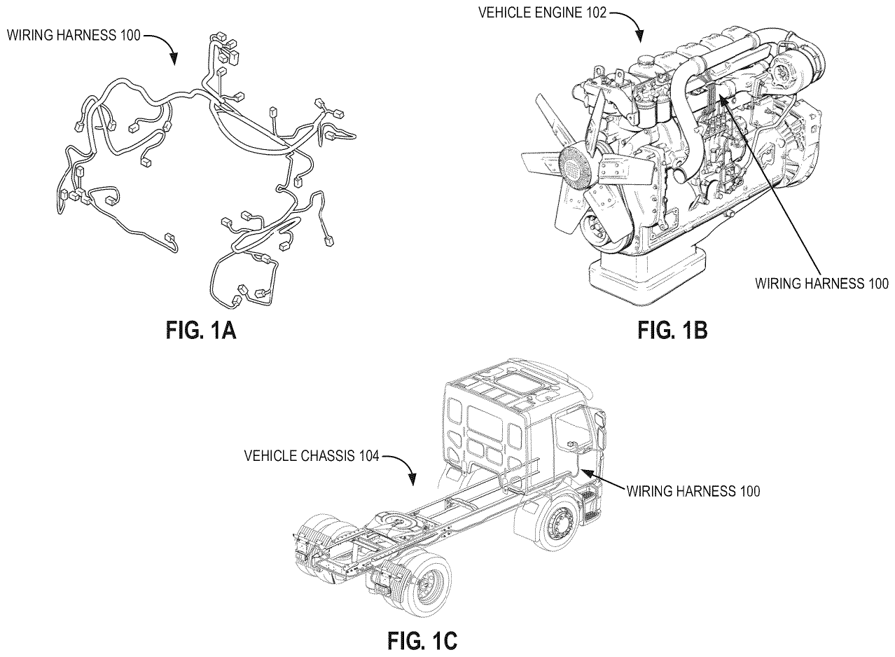

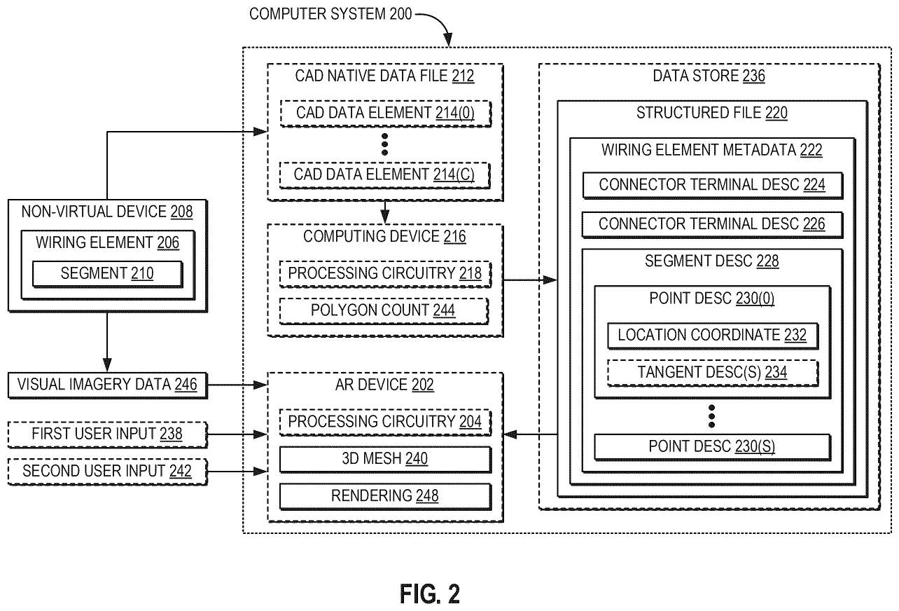

In this regard, FIG. 2 illustrates an exemplary computer system 200 that is configured to automatically generate on-demand wiring element optimized meshes for AR devices. In the example of FIG. 2, the computer system 200 includes an AR device 202 that comprises processing circuitry 204. The AR device 202 may comprise, e.g., a smartphone, a tablet device, a specialized AR headset, and/or a set of specialized AR glasses, as non-limiting examples. The AR device 202 may be used to visualize a wiring element 206 of a non-virtual device 208. The non-virtual device 208 may comprise a vehicle or an industrial machine, as non-limiting examples, while the wiring element 206 may comprise a wire, a wiring bundle, a wiring harness such as the wiring harness 100 of FIGS. 1A-1C, and/or the like, as non-limiting examples. The wiring element 206 comprises a segment 210 that represents a portion of the wiring element 206 between two connector terminals. It is to be understood that, while FIG. 2 illustrates only the singular segment 210 for the sake of clarity, in some examples the wiring element 206 may comprise a plurality of segments 210.

As seen in FIG. 2, the computer system 200 in some examples may include a CAD native data file 212 that defines a 3D model of the wiring element 206. The CAD native data file 212 may comprise an open-source or proprietary CAD data file format. The CAD native data file 212 in such examples comprises a plurality of CAD data elements 214(0)-214(C) that each define or represent a constituent element of the wiring element 206 and/or a characteristic or attribute of the constituent element, and that together can be used by appropriate CAD software to render a 3D representation of the wiring element 206. Thus, for example, the CAD data elements 214(0)-214(C) may represent the location and appearance of constituent elements such as connector terminals, and may further represent points through which wires or wire bundles may pass. The CAD data elements 214(0)-214(C) may also represent mesh geometry data, which as used herein may include data defining polygons or triangles with which the wiring element 206 and the constituent elements thereof may be rendered by CAD software and/or data defining spline geometry of the wiring element 206.

According to some examples, the computer system 200 also includes a computing device 216 that comprises processing circuitry 218. In such examples, the processing circuitry 218 may obtain the CAD native data file 212 corresponding to the wiring element 206, and may generate a structured file 220 based on the CAD native data file 212. The structured file 220 may comprise, e.g., an Extensible Markup Language (XML) file. As seen in FIG. 2, the structured file 220 comprises wiring element metadata 222 that includes a first connector terminal descriptor (captioned as “CONNECTOR TERMINAL DESC” in FIG. 2) 224, a second connector terminal descriptor (captioned as “CONNECTOR TERMINAL DESC” in FIG. 2) 226, and a segment descriptor (captioned as “SEGMENT DESC” in FIG. 2) 228 that corresponds to the segment 210 of the wiring element 206. The first connector terminal descriptor 224 and the second connector terminal descriptor 226 identify connector terminals that represent the endpoints of the wiring element 206. The segment descriptor 228 corresponds to a plurality of point descriptors (captioned as “POINT DESC” in FIG. 2) 230(0)-230(S). The point descriptor 230(0) shown in FIG. 2 includes a location coordinate 232 that represents a location in 3D space of a corresponding point. In some examples, the point descriptor 230(0) may also include one or more corresponding tangent descriptors (captioned as “TANGENT DESC(S)” in FIG. 2) 234 that represent incoming and/or outgoing tangents of the segment 210 as it passes through the corresponding point. While not shown in FIG. 2, it is to be understood that all of the point descriptors 230(0)-230(S) include elements corresponding to, e.g., the location coordinate 232 and the one or more tangent descriptors 234 of the point descriptor 230(0) shown in FIG. 2. It is to be further understood that the structured file 220 omits mesh geometry data for the wiring element 206.

In some such examples, the processing circuitry 218 may generate the structured file 220 by identifying a CAD data element within the CAD native data file 212 (such as the CAD data element 214(0)) that corresponds the first connector terminal descriptor 224, the second connector terminal descriptor 226, the segment descriptor 228, or a point descriptor of the plurality of point descriptors 230(0)-230(S) of the segment descriptor 228. The processing circuitry 218 then generates the wiring element metadata 222 based on the identified CAD data element 214(0), and stores the structured file 220 (e.g., in a data store 236 from which the AR device 202 can access the structured file 220).

To visualize the wiring element 206, the processing circuitry 204 of the AR device 202 obtains the structured file 220 corresponding to the wiring element 206 of the non-virtual device 208. The structure file 220 may be obtained by, e.g., by downloading or otherwise remotely accessing the structured file 220 stored on a computing device remote to the AR device 202, and/or by accessing the structured file 220 stored on a local storage device of the AR device 202, as non-limiting examples. The processing circuitry 204 in some examples may obtain the structured file 220 responsive to receiving a first user input 238 indicating a selection of the non-virtual device 208. The processing circuitry 204 then generates a 3D mesh 240 for the wiring element 206 based on the structured file 220. Some examples may provide that the processing circuitry 204 generates the 3D mesh 240 responsive to receiving a second user input 242 indicating a selection of the wiring element 206.

According to some examples, the processing circuitry may generate the 3D mesh 240 by determining a polygon count 244 for the segment 210. The polygon count 244 may be determined based on, e.g., a length of the segment 210 and the location coordinates and the one or more tangent descriptors of the plurality of point descriptors 230(0)-230(S) of the segment descriptor 228. The processing circuitry 204 then renders the segment 210 using the determined polygon count 244. In this manner, the 3D mesh 240 may be dynamically optimized based on maximizing the visual quality of the 3D mesh 240 while minimizing the polygon count 244 to improve device performance. The processing circuitry 204 then receives visual imagery data 246 of the non-virtual device 208. The visual imagery data 246 may comprise, e.g., a live video stream of the non-virtual device 208 that is captured by the AR device 202. The processing circuitry 204 displays a rendering 248 of the 3D mesh 240 overlaid on the visual imagery data 246 of the non-virtual device 208.

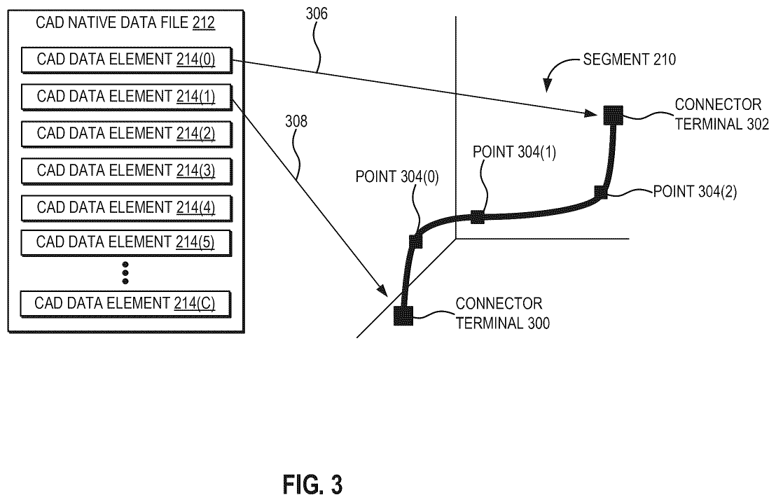

FIG. 3 is a block diagram illustrating exemplary constituent elements of the CAD native data file 212 of FIG. 2 and corresponding exemplary constituent elements of the segment 210 of FIG. 2 according to an example. In FIG. 3, the segment 210 of FIG. 2 is shown as it may be rendered by a CAD application according to some examples. The segment 210 comprises a first connector terminal (captioned as “CONNECTOR TERMINAL in FIG. 3”) 300 and a second connector terminal (captioned as “CONNECTOR TERMINAL in FIG. 3”) 302 that correspond to the first connector terminal descriptor 224 and the second connector terminal descriptor 226 of FIG. 2, and that define the endpoints of the wiring element 206 of FIG. 2. The segment 210 further comprises points 304(0)-304(2), each of which represents a location in 3D space through which the segment 210 flows.

In the example of FIG. 3, the CAD data elements 214(0)-214(C) of the CAD native data file 212 define a CAD model of the segment 210 as shown in FIG. 3. For instance, the CAD data element 214(0) in this example corresponds to and defines the characteristics of the connector terminal 302 as indicated by arrow 306, while the CAD data element 214(1) corresponds to and defines the characteristics of the connector terminal 300 as indicated by arrow 308. In similar fashion, the CAD data elements 214(2)-214(4) may correspond to and define the characteristics of the points 304(0)-304(2), respectively. The remaining CAD data elements 214(5)-214(C) may provide other data for the CAD model of the segment 210, such as mesh geometry data, that is not used when generating the structured file 220 of FIG. 2.

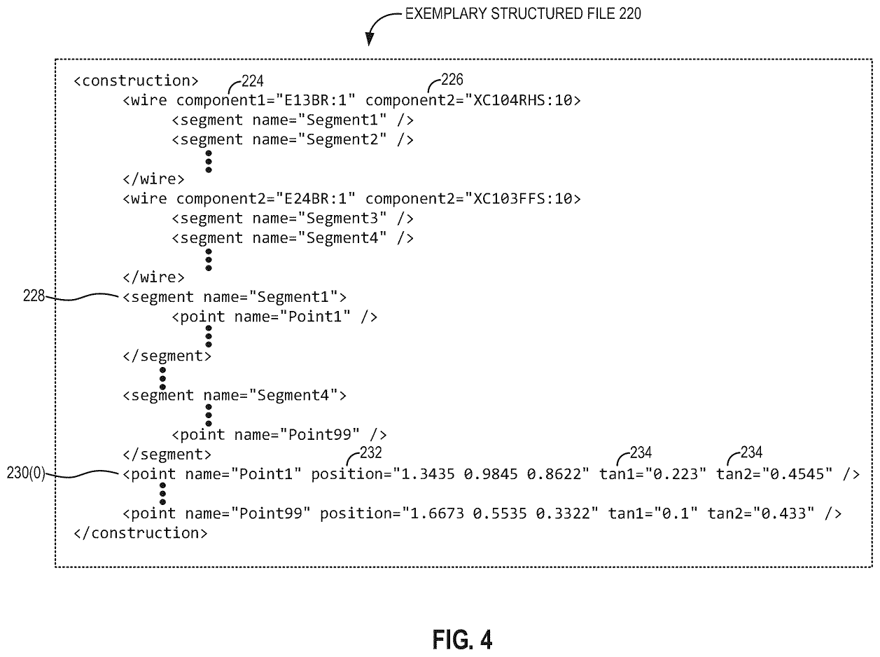

To illustrate exemplary constituent elements of the structured file 220 of FIG. 2 according to an example, FIG. 4 is provided. As seen in FIG. 4, the structured file 220 in this example comprises an XML file that may be generated based on a CAD native data file such as the CAD native data file of FIGS. 2 and 3. The first connector terminal descriptor 224 and the second connector terminal descriptor 226 are provided as attributes of a “wire” node that corresponds to the wiring element 206 of FIG. 2. The segment descriptor 228 is represented by a “segment” node that may correspond to multiple “point” nodes, each of which in turn corresponds to one of the point descriptors 230(0)-230(S) of FIG. 2 (note that only the point descriptor 230(0) is represented in FIG. 4 for the sake of clarity). Finally, a “point” node corresponding to the point descriptor 230(0) of FIG. 2 includes a “position” attribute that corresponds to the location coordinate 232 of FIG. 2, and also includes “tan1” and “tan2” attributes that correspond to the one or more tangent descriptors 234 of FIG. 2. It is to be understood that some examples may provide that the contents of the structured file 220 may differ from that illustrated in FIG. 4 according to the requirements of such examples, and thus may include more, fewer, or different nodes and/or attributes than those illustrated in FIG. 4.

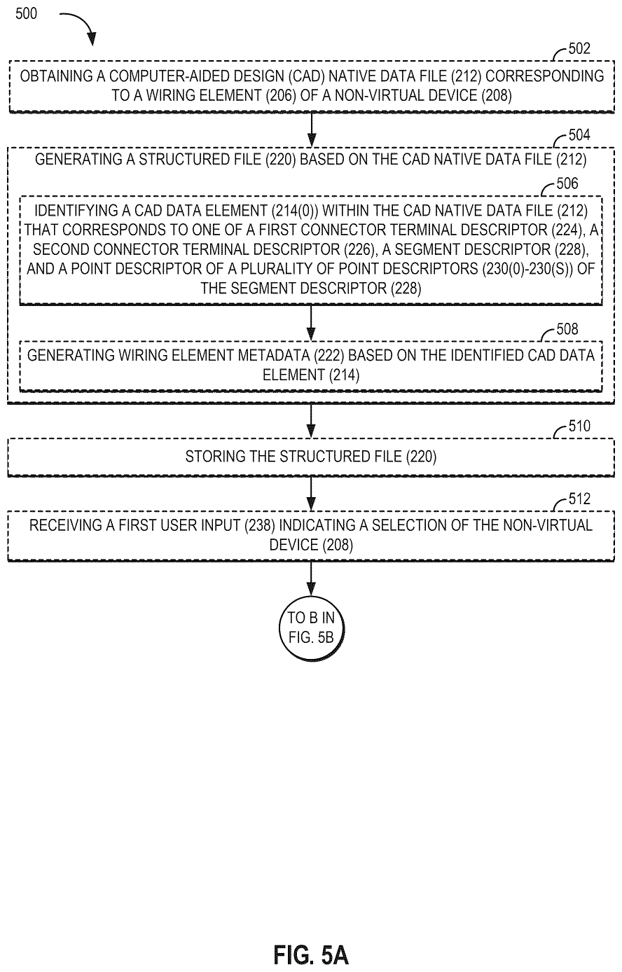

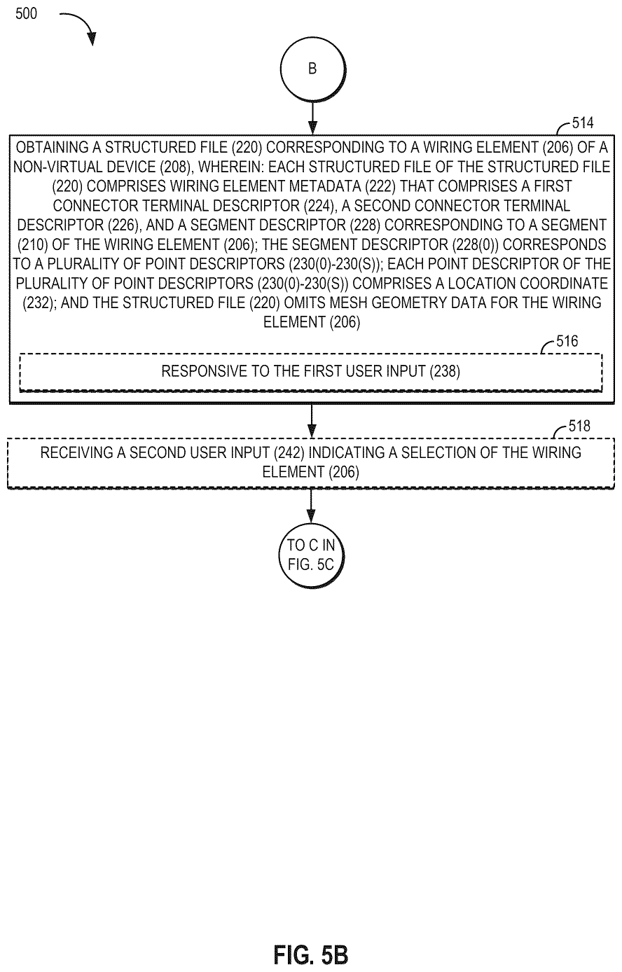

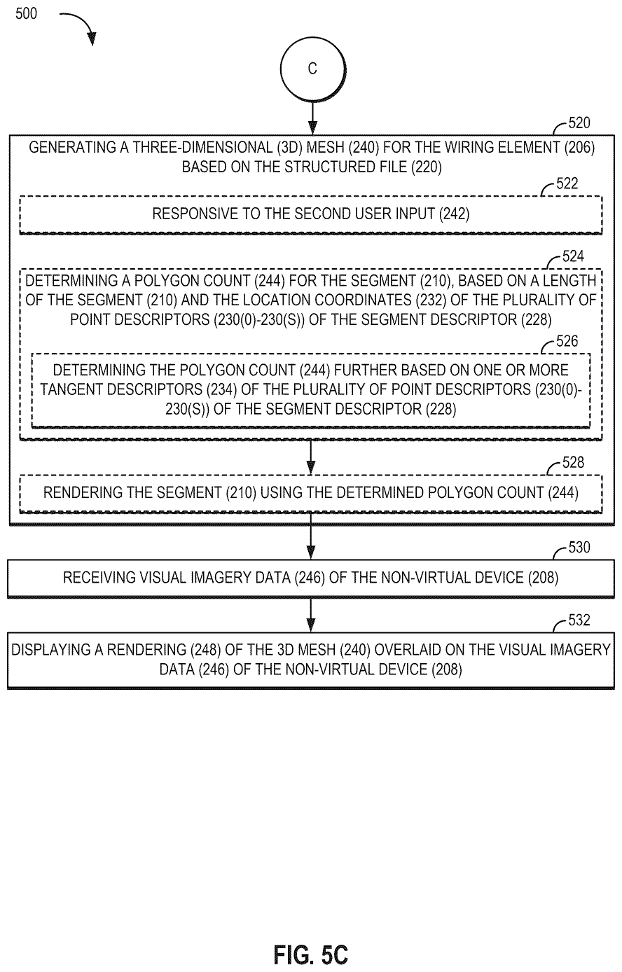

FIGS. 5A-5C provide a flow chart of an exemplary method to automatically generate on-demand wiring element optimized meshes for AR devices according to an example. FIGS. 5A-5C show exemplary operations 500, with elements of FIG. 2 being referenced in describing FIGS. 5A-5C for the sake of clarity. In FIG. 5A, the exemplary operations 500 in some examples begins with processing circuitry (e.g., the processing circuitry 204 of FIG. 2) of a computer system (such as the computer system 200 of FIG. 2) obtaining a CAD native data file (e.g., the CAD native data file 212 of FIG. 2) corresponding to a wiring element (e.g., the wiring element 206 of FIG. 2) of a non-virtual device (such as the non-virtual device 208 of FIG. 2) (block 502 of FIG. 5A). The processing circuitry 204 generates a structured file (e.g., the structured file 220 of FIG. 2) based on the CAD native data file 212 (block 504 of FIG. 5A). According to some examples, the operations of block 504 for generating the structured file 220 may comprise the processing circuitry 204 identifying a CAD data element (such as the CAD data element 214(0) of FIG. 2) within the CAD native data file 212 that corresponds to one of a first connector terminal descriptor (e.g., the connector terminal descriptor 224 of FIG. 2), a second connector terminal descriptor (such as the connector terminal descriptor 226 of FIG. 2), a segment descriptor (e.g., the segment descriptor 228 of FIG. 2), and a point descriptor of a plurality of point descriptors (such as the point descriptors 230(0)-230(S) of FIG. 2) of the segment descriptor 228 (block 506 of FIG. 5A). The processing circuitry 204 then generates wiring element metadata (e.g., the wiring element metadata 222 of FIG. 2) based on the identified CAD data element 214(0) (block 508 of FIG. 5A). The processing circuitry 204 in such examples then stores the structured file 220 (block 510 of FIG. 5A). Some examples may further provide that the processing circuitry 204 receives a first user input (such as the first user input 238 of FIG. 2) indicating a selection of the non-virtual device 208 (block 512 of FIG. 5A). The exemplary operations 500 then continue at block 514 of FIG. 5B.

Turning now to FIG. 5B, the processing circuitry 204 obtains a structured file (e.g., the structured file 220 of FIG. 2) corresponding to the wiring element 206 of the non-virtual device 208 (block 514 of FIG. 5B). As noted above, the structured file 220 comprises the wiring element metadata 222 of FIG. 2 that comprises the first connector terminal descriptor 224 of FIG. 2, the second connector terminal descriptor 226 of FIG. 2, and the segment descriptor 228 of FIG. 2 that corresponds to the segment 210 of the wiring element 206. Additionally, the segment descriptor 228 comprises the plurality of point descriptors 230(0)-230(S) of FIG. 2, and each point descriptor of the plurality of point descriptors 230(0)-230(S) comprises the location coordinate 232 of FIG. 2. Finally, the structured file 220 omits mesh geometry data for the wiring element 206. In some examples, the operations of block 514 for obtaining the structured file 220 may be performed by the processing circuitry 204 responsive to the first user input 238 (block 516 of FIG. 5B). Some examples may provide that the processing circuitry 204 receives a second user input (such as the second user input 242 of FIG. 2) indicating a selection of the wiring element 206 (block 518 of FIG. 5B). The exemplary operations 500 then continue at block 520 of FIG. 5C.

Referring now to FIG. 5C, the processing circuitry 204 generates a 3D mesh (e.g., the 3D mesh 240 of FIG. 2) for the wiring element 206 based on the structured file 220 (block 520 of FIG. 5C). According to some examples, the operations of block 520 for generating the 3D mesh 240 may be performed by the processing circuitry 204 responsive to the second user input 242 (block 522 of FIG. 5C). In some examples, the operations of block 520 for generating the 3D mesh 240 may comprise the processing circuitry 204 determining a polygon count (e.g., the polygon count 244 of FIG. 2) for the segment 210, based on a length of the segment 210 and the location coordinates 232 of the plurality of point descriptors 230(0)-230(S) of the segment descriptor 228 (block 524 of FIG. 5C). Some such examples may further provide that the operations of block 524 for determining the polygon count 244 are further based on one or more tangent descriptors (such as the one or more tangent descriptors 234 of FIG. 2) of the plurality of point descriptors 230(0)-230(S) of the segment descriptor 228 (block 526 of FIG. 5C). The processing circuitry 204 then renders the segment 210 using the determined polygon count 244 (block 528 of FIG. 5C).

The processing circuitry 204 then receives visual imagery data (such as the visual imagery data 246 of FIG. 2) of the non-virtual device 208 (block 530 of FIG. 5C). The processing circuitry 204 displays a rendering (such as the rendering 248 of FIG. 2) of the 3D mesh 240 overlaid on the visual imagery data 246 of the non-virtual device 208 (block 532 of FIG. 5C).

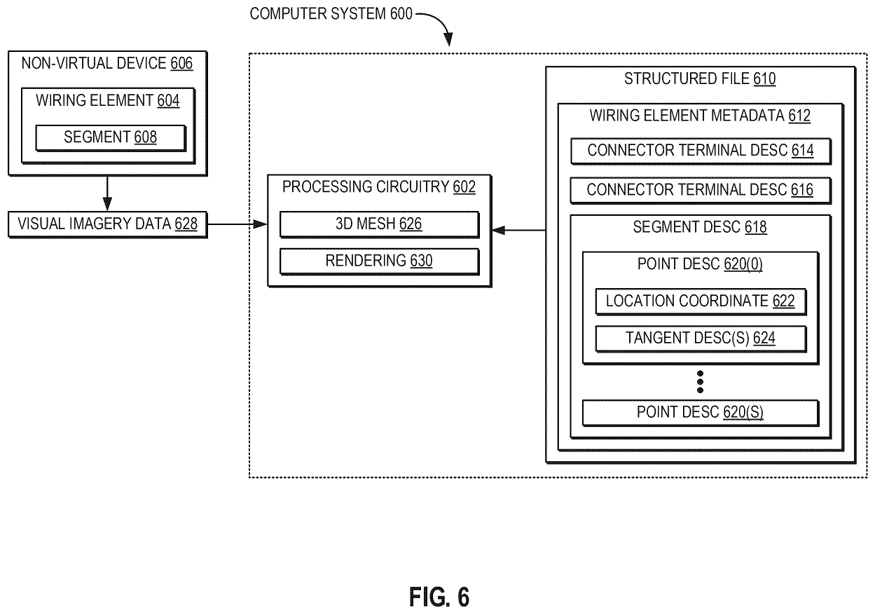

FIG. 6 is another view of the computer system 200 of FIG. 2 according to an example. In FIG. 6, an exemplary computer system 600 comprises processing circuitry 602 that is configured to enable visualization of a wiring element 604 of a non-virtual device 606. The wiring element 604 comprises a segment 608 that represents a portion of the wiring element 604 between two connector terminals.

To visualize the wiring element 604, the processing circuitry 602 obtains (e.g., by downloading or otherwise remotely accessing) a structured file 610 corresponding to the wiring element 604 of the non-virtual device 606. The structured file 610 comprises wiring element metadata 612 that includes a first connector terminal descriptor (captioned as “CONNECTOR TERMINAL DESC” in FIG. 6) 614, a second connector terminal descriptor (captioned as “CONNECTOR TERMINAL DESC” in FIG. 6) 616, and a segment descriptor (captioned as “SEGMENT DESC” in FIG. 6) 618 that corresponds to the segment 608 of the wiring element 604. The segment descriptor 618 corresponds to a plurality of point descriptors (captioned as “POINT DESC” in FIG. 6) 620(0)-620(S). The point descriptor 620(0) shown in FIG. 6 includes a location coordinate 622 that represents a location in 3D space of a corresponding point, and one or more corresponding tangent descriptors (captioned as “TANGENT DESC(S)” in FIG. 6) 624 that represent incoming and/or outgoing tangents of the segment 608 as it passes through the corresponding location. While not shown in FIG. 6, it is to be understood that all of the point descriptors 620(0)-620(S) include elements corresponding to the location coordinate 622 and the one or more tangent descriptors 624 of the point descriptor 620(0) shown in FIG. 6. It is to be further understood that the structured file 610 omits mesh geometry data for the wiring element 604.

The processing circuitry 602 then generates a 3D mesh 626 for the wiring element 604 based on the structured file 610. The processing circuitry 602 receives visual imagery data 628 of the non-virtual device 606, and displays a rendering 630 of the 3D mesh 626 overlaid on the visual imagery data 628 of the non-virtual device 606.

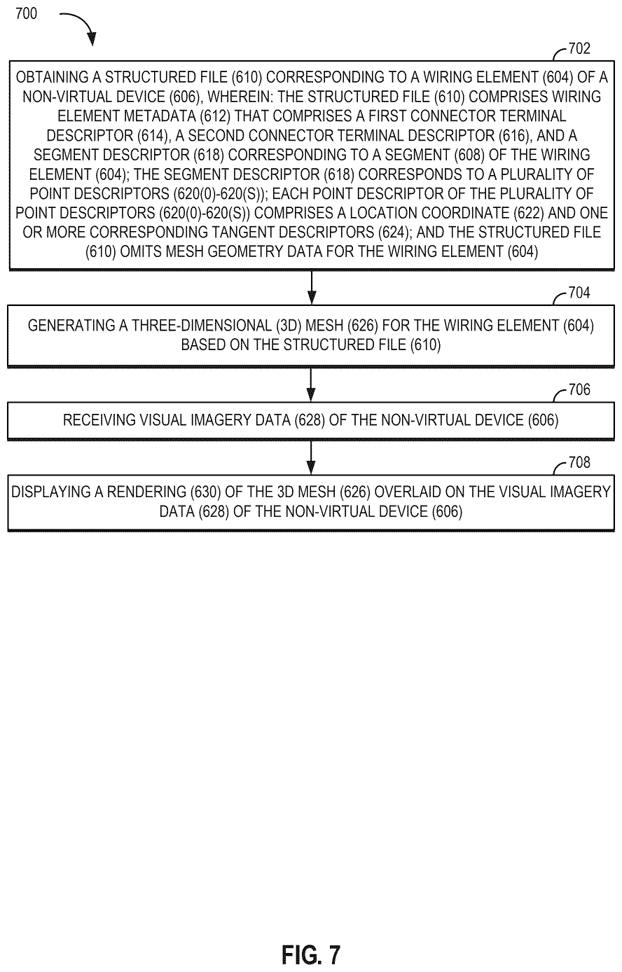

FIG. 7 is a flow chart of an exemplary method to automatically generate on-demand wiring element optimized meshes for AR devices according to an example. In FIG. 7, exemplary operations 700 are shown, with elements of FIG. 6 being referenced in describing FIG. 7 for the sake of clarity. The exemplary operations 700 in FIG. 7 begin with processing circuitry (e.g., the processing circuitry 602 of FIG. 6) of a computer system (such as the computer system 600 of FIG. 6) obtaining a structured file (e.g., the structured file 610 of FIG. 6) corresponding to a wiring element (such as the wiring element 604 of FIG. 6) of a non-virtual device (e.g., the non-virtual device 606 of FIG. 6) (block 702 of FIG. 7). As noted above, the structured file 610 comprises the wiring element metadata 612 of FIG. 6 that comprises the first connector terminal descriptor 614 of FIG. 6, the second connector terminal descriptor 616 of FIG. 6, and the segment descriptor 618 of FIG. 6 that corresponds to the segment 608 of the wiring element 604. Additionally, the segment descriptor 618 comprises the plurality of point descriptors 620(0)-620(S) of FIG. 6, and each point descriptor of the plurality of point descriptors 620(0)-620(S) comprises the location coordinate 622 of FIG. 6 and the one or more corresponding tangent descriptors 624 of FIG. 6. Finally, the structured file 610 omits mesh geometry data for the wiring element 604.

The processing circuitry 602 generates a 3D mesh (such as the 3D mesh 626 of FIG. 6) for the wiring element 604 based on the structured file 610 (block 704 of FIG. 7). The processing circuitry 602 next receives visual imagery data (e.g., the visual imagery data 628 of FIG. 6) of the non-virtual device 606 (block 706 of FIG. 7). The processing circuitry 602 then displays a rendering (such as the rendering 630 of FIG. 6) of the 3D mesh 626 overlaid on the visual imagery data 628 of the non-virtual device 606 (block 708 of FIG. 7).

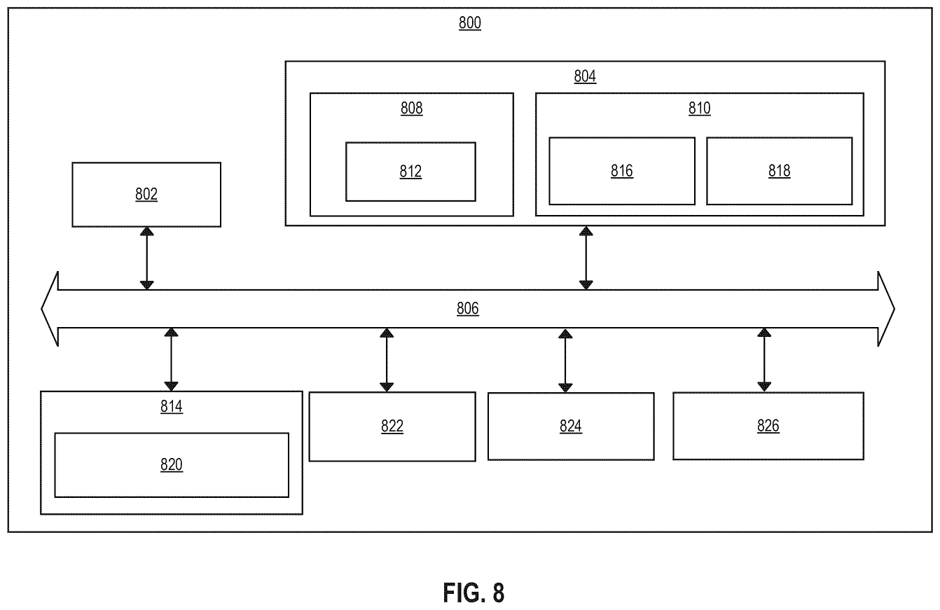

FIG. 8 is a schematic diagram of a computer system 800 for implementing examples disclosed herein. The computer system 800 is adapted to execute instructions from a computer-readable medium to perform these and/or any of the functions or processing described herein. The computer system 800 may be connected (e.g., networked) to other machines in a LAN (Local Area Network), LIN (Local Interconnect Network), automotive network communication protocol (e.g., FlexRay), an intranet, an extranet, or the Internet. While only a single device is illustrated, the computer system 800 may include any collection of devices that individually or jointly execute a set (or multiple sets) of instructions to perform any one or more of the methodologies discussed herein. Accordingly, any reference in the disclosure and/or claims to a computer system, computing system, computer device, computing device, control system, control unit, electronic control unit (ECU), processor device, processing circuitry, etc., includes reference to one or more such devices to individually or jointly execute a set (or multiple sets) of instructions to perform any one or more of the methodologies discussed herein. For example, control system may include a single control unit or a plurality of control units connected or otherwise communicatively coupled to each other, such that any performed function may be distributed between the control units as desired. Further, such devices may communicate with each other or other devices by various system architectures, such as directly or via a Controller Area Network (CAN) bus, etc.

The computer system 800 may comprise at least one computing device or electronic device capable of including firmware, hardware, and/or executing software instructions to implement the functionality described herein. The computer system 800 may include processing circuitry 802 (e.g., processing circuitry including one or more processor devices or control units), a memory 804, and a system bus 806. The computer system 800 may include at least one computing device having the processing circuitry 802. The system bus 806 provides an interface for system components including, but not limited to, the memory 804 and the processing circuitry 802. The processing circuitry 802 may include any number of hardware components for conducting data or signal processing or for executing computer code stored in memory 804. The processing circuitry 802 may, for example, include a general-purpose processor, an application specific processor, a Digital Signal Processor (DSP), an Application Specific Integrated Circuit (ASIC), a Field Programmable Gate Array (FPGA), a circuit containing processing components, a group of distributed processing components, a group of distributed computers configured for processing, or other programmable logic device, discrete gate or transistor logic, discrete hardware components, or any combination thereof designed to perform the functions described herein. The processing circuitry 802 may further include computer executable code that controls operation of the programmable device.

The system bus 806 may be any of several types of bus structures that may further interconnect to a memory bus (with or without a memory controller), a peripheral bus, and/or a local bus using any of a variety of bus architectures. The memory 804 may be one or more devices for storing data and/or computer code for completing or facilitating methods described herein. The memory 804 may include database components, object code components, script components, or other types of information structure for supporting the various activities herein. Any distributed or local memory device may be utilized with the systems and methods of this description. The memory 804 may be communicably connected to the processing circuitry 802 (e.g., via a circuit or any other wired, wireless, or network connection) and may include computer code for executing one or more processes described herein. The memory 804 may include non-volatile memory 808 (e.g., read-only memory (ROM), erasable programmable read-only memory (EPROM), electrically erasable programmable read-only memory (EEPROM), etc.), and volatile memory 810 (e.g., random-access memory (RAM)), or any other medium which can be used to carry or store desired program code in the form of machine-executable instructions or data structures and which can be accessed by a computer or other machine with processing circuitry 802. A basic input/output system (BIOS) 812 may be stored in the non-volatile memory 808 and can include the basic routines that help to transfer information between elements within the computer system 800.

The computer system 800 may further include or be coupled to a non-transitory computer-readable storage medium such as the storage device 814, which may comprise, for example, an internal or external hard disk drive (HDD) (e.g., enhanced integrated drive electronics (EIDE) or serial advanced technology attachment (SATA)), HDD (e.g., EIDE or SATA) for storage, flash memory, or the like. The storage device 814 and other drives associated with computer-readable media and computer-usable media may provide non-volatile storage of data, data structures, computer-executable instructions, and the like.

Computer-code which is hard or soft coded may be provided in the form of one or more modules. The module(s) can be implemented as software and/or hard-coded in circuitry to implement the functionality described herein in whole or in part. The modules may be stored in the storage device 814 and/or in the volatile memory 810, which may include an operating system 816 and/or one or more program modules 818. All or a portion of the examples disclosed herein may be implemented as a computer program 820 stored on a transitory or non-transitory computer-usable or computer-readable storage medium (e.g., single medium or multiple media), such as the storage device 814, which includes complex programming instructions (e.g., complex computer-readable program code) to cause the processing circuitry 802 to carry out actions described herein. Thus, the computer-readable program code of the computer program 820 can comprise software instructions for implementing the functionality of the examples described herein when executed by the processing circuitry 802. In some examples, the storage device 814 may be a computer program product (e.g., readable storage medium) storing the computer program 820 thereon, where at least a portion of a computer program 820 may be loadable (e.g., into a processor) for implementing the functionality of the examples described herein when executed by the processing circuitry 802. The processing circuitry 802 may serve as a controller or control system for the computer system 800 that is to implement the functionality described herein.

The computer system 800 may include an input device interface 822 configured to receive input and selections to be communicated to the computer system 800 when executing instructions, such as from a keyboard, mouse, touch-sensitive surface, etc. Such input devices may be connected to the processing circuitry 802 through the input device interface 822 coupled to the system bus 806 but can be connected through other interfaces, such as a parallel port, an Institute of Electrical and Electronic Engineers (IEEE) 1394 serial port, a Universal Serial Bus (USB) port, an IR interface, and the like. The computer system 800 may include an output device interface 824 configured to forward output, such as to a display, a video display unit (e.g., a liquid crystal display (LCD) or a cathode ray tube (CRT)). The computer system 800 may include a communications interface 826 suitable for communicating with a network as appropriate or desired.

The operational actions described in any of the exemplary aspects herein are described to provide examples and discussion. The actions may be performed by hardware components, may be embodied in machine-executable instructions to cause a processor to perform the actions, or may be performed by a combination of hardware and software. Although a specific order of method actions may be shown or described, the order of the actions may differ. In addition, two or more actions may be performed concurrently or with partial concurrence.

Implementation examples are described in the following numbered clauses:

Example 1: A computer system comprising processing circuitry configured to:
obtain a structured file corresponding to a wiring element of a non-virtual device, wherein:
   the structured file comprises wiring element metadata that comprises a first connector terminal descriptor, a second connector terminal descriptor, and a segment descriptor corresponding to a segment of the wiring element;
   the segment descriptor corresponds to a plurality of point descriptors;
   each point descriptor of the plurality of point descriptors comprises a location coordinate in three-dimensional (3D) space; and
   the structured file omits mesh geometry data for the wiring element;
generate a 3D mesh for the wiring element based on the structured file;
receive visual imagery data of the non-virtual device; and
display a rendering of the 3D mesh overlaid on the visual imagery data of the non-virtual device.

Example 2: The computer system of example 1, wherein the processing circuitry is further configured to:
obtain a Computer-Aided Design (CAD) native data file corresponding to the wiring element;
generate the structured file based on the CAD native data file; and
store the structured file.

Example 3: The computer system of any one of examples 1-2, wherein the processing circuitry is configured to generate the structured file based on the CAD native data file by being configured to:
identify a CAD data element within the CAD native data file that corresponds to one of the first connector terminal descriptor, the second connector terminal descriptor, the segment descriptor, and a point descriptor of the plurality of point descriptors of the segment descriptor; and
generate the wiring element metadata based on the identified CAD data element.

Example 4: The computer system of any one of examples 1-3, wherein the processing circuitry is configured to generate the 3D mesh for the wiring element based on the structured file by being configured to:
determine a polygon count for the segment, based on a length of the segment and the location coordinates of the plurality of point descriptors of the segment descriptor; and
render the segment using the determined polygon count.

Example 5: The computer system of any one of examples 1-4, wherein:
each point descriptor of the plurality of point descriptors further comprises one or more corresponding tangent descriptors; and
the processing circuitry is configured to determine the polygon count for the segment further based on the one or more tangent descriptors of the plurality of point descriptors of the segment descriptor.

Example 6: The computer system of any one of examples 1-5, wherein:
the processing circuitry is further configured to receive a first user input indicating a selection of the non-virtual device; and
the processing circuitry is configured to obtain the structured file corresponding to the wiring element of the non-virtual device responsive to the first user input.

Example 7: The computer system of any one of examples 1-6, wherein:
the processing circuitry is further configured to receive a second user input indicating a selection of the wiring element; and
the processing circuitry is configured to generate the 3D mesh based on the structured file responsive to the second user input.

Example 8: The computer system of any one of examples 1-7, wherein the wiring element comprises one of a wire, a wiring bundle, and a wiring harness.

Example 9: The computer system of any one of examples 1-8, wherein the non-virtual device comprises a vehicle.

Example 10: A computer-implemented method, comprising:
obtaining, by processing circuitry of a computer system, a structured file corresponding to a wiring element of a non-virtual device, wherein:
   the structured file comprises wiring element metadata that comprises a first connector terminal descriptor, a second connector terminal descriptor, and a segment descriptor corresponding to a segment of the wiring element;
   the segment descriptor corresponds to a plurality of point descriptors;
   each point descriptor of the plurality of point descriptors comprises a location coordinate in three-dimensional (3D) space; and
   the structured file omits mesh geometry data for the wiring element;
generating, by the processing circuitry, a 3D mesh for the wiring element based on the structured file;
receiving, by the processing circuitry, visual imagery data of the non-virtual device; and
displaying, by the processing circuitry, a rendering of the 3D mesh overlaid on the visual imagery data of the non-virtual device.

Example 11: The computer-implemented method of example 10, further comprising:
obtaining, by the processing circuitry, a Computer-Aided Design (CAD) native data file corresponding to the wiring element;
generating, by the processing circuitry, the structured file based on the CAD native data file; and
storing, by the processing circuitry, the structured file.

Example 12: The computer-implemented method of any one of examples 10-11, wherein generating the structured file based on the CAD native data file comprises:
identifying, by the processing circuitry, a CAD data element within the CAD native data file that corresponds to one of the first connector terminal descriptor, the second connector terminal descriptor, the segment descriptor, and a point descriptor of the plurality of point descriptors of the segment descriptor; and
generating, by the processing circuitry, the wiring element metadata based on the identified CAD data element.

Example 13: The computer-implemented method of any one of examples 10-12, wherein generating the 3D mesh for the wiring element based on the structured file comprises:
determining, by the processing circuitry, a polygon count for the segment, based on a length of the segment and the location coordinates of the plurality of point descriptors of the segment descriptor; and
rendering, by the processing circuitry, the segment using the determined polygon count.

Example 14: The computer-implemented method of any one of examples 10-13, wherein:
each point descriptor of the plurality of point descriptors further comprises one or more corresponding tangent descriptors; and
determining the polygon count for the segment is further based on the one or more tangent descriptors of the plurality of point descriptors of the segment descriptor.

Example 15: The computer-implemented method of any one of examples 10-14, further comprising receiving, by the processing circuitry, a first user input indicating a selection of the non-virtual device;
wherein obtaining the structured file corresponding to the wiring element of the non-virtual device is responsive to the first user input.

Example 16: The computer-implemented method of any one of examples 10-15, further comprising receiving, by the processing circuitry, a second user input indicating a selection of the wiring element;
wherein generating the 3D mesh based on the structured file is responsive to the second user input.

Example 17: The computer-implemented method of any one of examples 10-16, wherein the wiring element comprises one of a wire, a wiring bundle, and a wiring harness.

Example 18: The computer-implemented method of any one of examples 10-17, wherein the non-virtual device comprises a vehicle.

Example 110: A computer program product comprising program code for performing, when executed by the processing circuitry, the method of any of examples 10-18.

Example 20: A non-transitory computer-readable storage medium comprising instructions, which when executed by the processing circuitry, cause the processing circuitry to perform the method of any of examples 10-18.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. As used herein, the term “and/or” includes any and all combinations of one or more of the associated listed items. It will be further understood that the terms “comprises,” “comprising,” “includes,” and/or “including” when used herein specify the presence of stated features, integers, actions, steps, operations, elements, and/or components, but do not preclude the presence or addition of one or more other features, integers, actions, steps, operations, elements, components, and/or groups thereof.

It will be understood that, although the terms first, second, etc., may be used herein to describe various elements, these elements should not be limited by these terms. These terms are only used to distinguish one element from another. For example, a first element could be termed a second element, and, similarly, a second element could be termed a first element without departing from the scope of the present disclosure.

Relative terms such as “below” or “above” or “upper” or “lower” or “horizontal” or “vertical” may be used herein to describe a relationship of one element to another element as illustrated in the Figures. It will be understood that these terms and those discussed above are intended to encompass different orientations of the device in addition to the orientation depicted in the Figures. It will be understood that when an element is referred to as being “connected” or “coupled” to another element, it can be directly connected or coupled to the other element, or intervening elements may be present. In contrast, when an element is referred to as being “directly connected” or “directly coupled” to another element, there are no intervening elements present.

Unless otherwise defined, all terms (including technical and scientific terms) used herein have the same meaning as commonly understood by one of ordinary skill in the art to which this disclosure belongs. It will be further understood that terms used herein should be interpreted as having a meaning consistent with their meaning in the context of this specification and the relevant art and will not be interpreted in an idealized or overly formal sense unless expressly so defined herein.

It is to be understood that the present disclosure is not limited to the aspects described above and illustrated in the drawings; rather, the skilled person will recognize that many changes and modifications may be made within the scope of the present disclosure and appended claims. In the drawings and specification, there have been disclosed aspects for purposes of illustration only and not for purposes of limitation, the scope of the disclosure being set forth in the following claims.

What is claimed is:

1. A computer system comprising processing circuitry configured to:
obtain a structured file corresponding to a wiring element of a non-virtual device, wherein:
the structured file comprises wiring element metadata that comprises a first connector terminal descriptor, a second connector terminal descriptor, and a segment descriptor corresponding to a segment of the wiring element;
the segment descriptor corresponds to a plurality of point descriptors;
each point descriptor of the plurality of point descriptors comprises a location coordinate in three-dimensional (3D) space; and
the structured file omits mesh geometry data for the wiring element;
generate a 3D mesh for the wiring element based on the structured file;
receive visual imagery data of the non-virtual device; and
display a rendering of the 3D mesh overlaid on the visual imagery data of the non-virtual device.

2. The computer system of claim 1, wherein the processing circuitry is further configured to:
obtain a Computer-Aided Design (CAD) native data file corresponding to the wiring element;
generate the structured file based on the CAD native data file; and
store the structured file.

3. The computer system of claim 1, wherein the processing circuitry is configured to generate the structured file based on the CAD native data file by being configured to:
identify a CAD data element within the CAD native data file that corresponds to one of the first connector terminal descriptor, the second connector terminal descriptor, the segment descriptor, and a point descriptor of the plurality of point descriptors of the segment descriptor; and
generate the wiring element metadata based on the identified CAD data element.

4. The computer system of claim 1, wherein the processing circuitry is configured to generate the 3D mesh for the wiring element based on the structured file by being configured to:
determine a polygon count for the segment, based on a length of the segment and the location coordinates of the plurality of point descriptors of the segment descriptor; and
render the segment using the determined polygon count.

5. The computer system of claim 1, wherein:
each point descriptor of the plurality of point descriptors further comprises one or more corresponding tangent descriptors; and
the processing circuitry is configured to determine the polygon count for the segment further based on the one or more tangent descriptors of the plurality of point descriptors of the segment descriptor.

6. The computer system of claim 1, wherein:
the processing circuitry is further configured to receive a first user input indicating a selection of the non-virtual device; and
the processing circuitry is configured to obtain the structured file corresponding to the wiring element of the non-virtual device responsive to the first user input.

7. The computer system of claim 1, wherein:
the processing circuitry is further configured to receive a second user input indicating a selection of the wiring element; and
the processing circuitry is configured to generate the 3D mesh based on the structured file responsive to the second user input.

8. The computer system of claim 1, wherein the wiring element comprises one of a wire, a wiring bundle, and a wiring harness.

9. The computer system of claim 1, wherein the non-virtual device comprises a vehicle.

10. A computer-implemented method, comprising:
obtaining, by processing circuitry of a computer system, a structured file corresponding to a wiring element of a non-virtual device, wherein:
the structured file comprises wiring element metadata that comprises a first connector terminal descriptor, a second connector terminal descriptor, and a segment descriptor corresponding to a segment of the wiring element;
the segment descriptor corresponds to a plurality of point descriptors;
each point descriptor of the plurality of point descriptors comprises a location coordinate in three-dimensional (3D) space; and
the structured file omits mesh geometry data for the wiring element;
generating, by the processing circuitry, a 3D mesh for the wiring element based on the structured file;
receiving, by the processing circuitry, visual imagery data of the non-virtual device; and
displaying, by the processing circuitry, a rendering of the 3D mesh overlaid on the visual imagery data of the non-virtual device.

11. The computer-implemented method of claim 10, further comprising:
obtaining, by the processing circuitry, a Computer-Aided Design (CAD) native data file corresponding to the wiring element;
generating, by the processing circuitry, the structured file based on the CAD native data file; and
storing, by the processing circuitry, the structured file.

12. The computer-implemented method of claim 10, wherein generating the structured file based on the CAD native data file comprises:
identifying, by the processing circuitry, a CAD data element within the CAD native data file that corresponds to one of the first connector terminal descriptor, the second connector terminal descriptor, the segment descriptor, and a point descriptor of the plurality of point descriptors of the segment descriptor; and
generating, by the processing circuitry, the wiring element metadata based on the identified CAD data element.

13. The computer-implemented method of claim 10, wherein generating the 3D mesh for the wiring element based on the structured file comprises:
determining, by the processing circuitry, a polygon count for the segment, based on a length of the segment and the location coordinates of the plurality of point descriptors of the segment descriptor; and
rendering, by the processing circuitry, the segment using the determined polygon count.

14. The computer-implemented method of claim 10, wherein:
each point descriptor of the plurality of point descriptors further comprises one or more corresponding tangent descriptors; and
determining the polygon count for the segment is further based on the one or more tangent descriptors of the plurality of point descriptors of the segment descriptor.

15. The computer-implemented method of claim 10, further comprising receiving, by the processing circuitry, a first user input indicating a selection of the non-virtual device;
wherein obtaining the structured file corresponding to the wiring element of the non-virtual device is responsive to the first user input.

16. The computer-implemented method of claim 10, further comprising receiving, by the processing circuitry, a second user input indicating a selection of the wiring element;
wherein generating the 3D mesh based on the structured file is responsive to the second user input.

17. The computer-implemented method of claim 10, wherein the wiring element comprises one of a wire, a wiring bundle, and a wiring harness.

18. The computer-implemented method of claim 10, wherein the non-virtual device comprises a vehicle.

19. A computer program product comprising program code for performing, when executed by the processing circuitry, the method of claim 10.

20. A non-transitory computer-readable storage medium comprising instructions, which when executed by the processing circuitry, cause the processing circuitry to perform the method of claim 10.
